(19) United States
(12) Patent Application Publication
(10) Pub. No.: US 2004/0080309 A1
(43) Pub. Date: Apr. 29, 2004

(54) Method for performing test measurements on electrical components

(76) Inventors: Peter Schmid, Wurzburg (DE); Robert Petter, Wandlitz (DE); Elmar Droge, Berlin (DE); Manfred Gewald, Regensburg (DE); Thomas Kassemodel, Berlin (DE); Daniel Reznik, Berlin (DE)

Correspondence Address: LERNER AND GREENBERG, P.A., POST OFFICE BOX 2480, HOLLYWOOD, FL, 33022-2480, US

(21) Appl. No.: 10/653,587

(22) Filed: Sep. 2, 2003

(30) Foreign Application Priority Data
Aug. 30, 2002 (DE) 102 41 045.3

(51) Int. Cl. G01R 1/00

(52) U.S. Cl. 324/158.1

(57) ABSTRACT

A method performs test measurements on electrical components. The components are firstly subjected to an aging process before the actual test measurements are performed on them. In order to be able to handle this in a particularly simple manner, the components are firstly disposed on a carrier with a switching matrix. In this case, the switching matrix is configured in such a way that all the components are switched on for the purpose of carrying out the aging process and exclusively the components to be measured—individually or in subgroups—are switched on for the purpose of carrying out the test measurements.

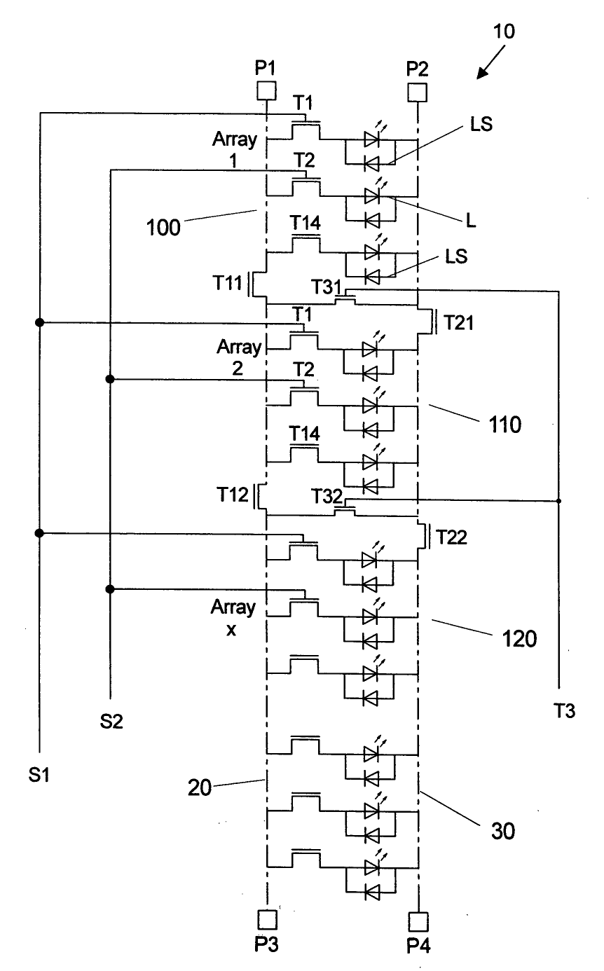

### BACKGROUND OF THE INVENTION

1. Field of the Invention

The invention relates to methods for performing test measurements on electrical components after the components have been subjected to an aging process that is performed simultaneously on all the components. In the past, such methods have been complicated and slow.

### SUMMARY OF THE INVENTION

It is accordingly an object of the invention to provide a method for performing test measurements on electrical components that overcomes the hereinafore-mentioned disadvantages of the heretofore-known devices of this general type and that can be carried out particularly simply and rapidly.

With the foregoing and other objects in view, there is provided, in accordance with the invention, a method for performing test measurements on electrical components. The first step of the method involves disposing components on a carrier with a switching matrix and connecting the components to the switching matrix to allow the components to be switched on or off selectively. The next step is driving the switching matrix to switch all of the components on for simultaneously carrying out an aging process on all of the components. The next step is performing the test measurements by exclusively switching on the components to be measured.

An important advantage of the method according to the invention is that the components are subjected to a predetermined aging process before the actual test measurements are carried out. Those components that already had defects and were faulty during production are primarily the ones that fail during the aging process. After the conclusion of the aging process—also called burn-in process in the case of lasers or light-emitting diodes—all that then remain are the components that are to be regarded as free of defects and that are anticipated to actually reach their expected service life. A further advantage of the method according to the invention is that preferably all the components are subjected to the aging process simultaneously in order to have the effect that the aging process is substantially identical for the components. Carrying out the aging process simultaneously for all the components results in a time saving compared with a sequential aging process in which the components are aged individually or successively. A third advantage of the method according to the invention is to be seen in the use of the switching matrix. Specifically, what is achieved in concrete terms through the use of the switching matrix is that, after the conclusion of the aging process carried out simultaneously on all the components, the components do not have to be contact-connected individually since the components can be switched on or activated individually or in subgroups with the aid of the switching matrix as soon as test measurements are intended to be carried out on them.

It is regarded as advantageous if a semiconductor material is used as the carrier material. Specifically, a use of semiconductor material advantageously enables the switching matrix to be formed at least partly by semiconductor switches at least partly monolithically integrated in the semiconductor material. The monolithic integration of the semiconductor switches in the semiconductor material makes it possible to achieve considerable cost advantages compared with a discrete construction of switches or semiconductor switches on a carrier.

With regard to cost considerations, it is regarded as advantageous if silicon is used as the semiconductor material for the carrier.

The semiconductor switches can advantageously be formed by transistors, in particular by field-effect transistors, in a semiconductor material.

The method according to the invention can be used in an advantageous manner in the case of light-emitting electrical components, that is to say, in particular, in the case of light-emitting diodes and laser diodes.

In order in this case to ensure that the light-emitting or laser diodes are not damaged when carrying out the aging process or when carrying out the test measurements, it is regarded as advantageous if a protective diode is in each case connected in parallel with the light-emitting or laser diodes before the aging process is carried out and/or before the test measurements are carried out. A protective diode can be connected to a light-emitting or laser diode for example in such a way that the anode of the protective diode is connected to the cathode of the light-emitting or laser diode and the cathode of the protective diode is connected to the anode of the light-emitting or laser diode.

Furthermore, it is regarded as advantageous if the method according to the invention is carried out on VCSEL lasers (vertical cavity surface emitting lasers); in this case, the VCSEL lasers are advantageously firstly mounted on a silicon carrier having an electronic switching matrix. The VCSEL lasers are then connected to the switching matrix; in order to carry out the aging process, the switching matrix is then driven in such a way that all the VCSEL lasers age simultaneously. After the conclusion of the aging process, the switching matrix is then changed over in such a way that each VCSEL laser can be measured individually. A very substantial advantage of this method is that the VCSEL lasers can be both aged and measured on the silicon carrier; a “modification” of the measuring device for carrying out the test measurements after the aging process is not necessary, therefore, thereby achieving a significant saving with respect to time and costs.

Other features that are considered as characteristic for the invention are set forth in the appended claims.

Although the invention is illustrated and described herein as embodied in a method for performing test measurements on electrical components, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWING

The FIGURE is a circuit diagram showing an exemplary embodiment of a switching matrix that can be used for carrying out the method according to the invention.

### DESCRIPTION OF THE PREFERRED EMBODIMENTS

Referring now to the single FIGURE of the drawing, it is seen that a switching matrix 10 has four terminals, namely a first terminal P1, a second terminal P2, a third terminal P3 and a fourth terminal P4. The switching matrix 10 is electrically subdivided into columns and rows, which will now be explained with reference to the FIGURE using the terms “columns” and “rows”.

Between the first and third terminals P1, P3, column transistors T11, T12, . . . are connected in series and form a column 20. Between the second terminal P2 and the fourth terminal P4, further column transistors T21, T22, . . . are connected in series and form a second column 30.

Laser arrays 100, 110 and 120 are connected between the two columns 20 and 30. Each laser array 100, 110, and 120 has 14 laser diodes L in each case, which are in each case connected in series with a switching transistor T1, T2, . . . , T14. The series circuit formed from laser diode L and switching transistor T1, T2, . . . and T14, respectively, is connected to the columns 20 and 30.

Electrically connected in parallel with the series circuit formed from laser diode L and switching transistor there is in each case a “row transistor” T31, T32, . . . per laser array; the row transistors T31, T32, etc. in each case isolate the laser arrays 100, 110, and 120 from one another in the “row direction”.

The base terminals of all the row transistors T31, T32, . . . are electrically interconnected and together form a control terminal T3 of the switching matrix 10.

Moreover, all the base terminals of the switching transistors T1 are in each case interconnected and thus form a control terminal S1. The same applies correspondingly to the switching transistors T2, whose base terminals are interconnected and together form a control terminal S2. In a corresponding manner, the remaining switching transistors T3-T14 of the laser arrays are interconnected to form control terminals S3-S14. The control terminals S3 to S14 are not illustrated in the FIGURE for the sake of clarity.

For the protection of the laser diodes L, a protective diode LS—with opposite polarity—is in each case connected in parallel with the laser diodes. The protective diode LS serves to prevent an overvoltage at the laser diode L in the reverse direction.

The switching matrix 10 of the FIGURE can be used to carry out test measurements on the lasers L, as will now be explained. In this case, the lasers L are intended firstly to be subjected to an aging process. During this aging process, all the components simultaneously are switched on and have current applied to them for a predetermined time.

After the conclusion of this aging process, also called burn-in process, the individual lasers L are then characterized in each case by themselves by the corresponding test signals being applied to the terminals P1-P4.

The text below will now describe how the column transistors and the row transistors in the switching matrix 10 have to be driven in order to enable the burn-in or aging process, on the one hand, and the actual test measurements, on the other hand.

In order to carry out the burn-in process, current flows through all the laser diodes L simultaneously. In order to achieve this, a positive voltage is applied to the terminals P1 and P4. All the column transistors T11, T12, . . . of the first column 20 and all the switching transistors T21, T22, . . . of the second column 30 are switched off simultaneously; the row transistors T31, T32, . . . , by contrast, are switched on via their control terminal T3.

With this circuitry of the row and column transistors, a current flow is produced as follows: firstly the current flows from the first contact P1 via the first laser array 100 to the second column 30. Because the topmost transistor T21 of the second column 30 in the FIGURE is then turned off, the current flows from the second column 30 via the row transistor T31 back to the first column 20, from where it passes via the second laser array 110, i.e. via all the switching transistors T1-T14 and the associated laser diodes L of the second laser array 110, to the second column 30 again.

Because the column transistor T22 of the second column 30 is in turn switched off, the current must flow from the second column 30 via the row transistor T32 to the first column 20 again, from where it flows back to the second column 30 via the laser array 120. To summarize, then, the current flows in each case from the first column 20 to the second column 30 via a laser array and from the second column 30 back to the first column 20 again via a row transistor; what is achieved in this way is that the current flows through all the laser arrays.

In this case, the current flow through the laser arrays is carried out for as long as is necessitated by the predetermined aging process. After the conclusion of this aging process, the laser diodes are then characterized individually. This requires a corresponding driving of the column and row transistors, which has to be effected as follows.

By way of example, if the intention is to measure the first laser diode of the first laser array 100, then voltage is applied to the first control terminal S1, which leads to an activation of all the switching transistors T1. The remaining switching transistors T2 to T14 and also the column transistors T11, T12, . . . of the first column 20 are switched off, thereby preventing a current flow through these transistors. The column transistors T21, T22, . . . of the second column 30, by contrast, are switched on in order to enable a current flow through these transistors. The row transistors T31, T32, . . . are switched off in their entirety via their control terminal T3.

Due to this driving of the column and row transistors, a measurement current will flow from the first terminal P1 via the activated transistor T1 and also via the assigned laser diode L to the second column 30, from where the current flows away via the activated column transistors T21, T22, . . . of the second column 30 to the fourth terminal P4 of the switching matrix 10.

The remaining transistors T2-T14 of the first laser array 100 can be measured in a corresponding manner by activation of the corresponding switching transistors T2-T14.

The remaining laser diodes L of the remaining laser arrays can also be driven in a corresponding manner. By way of example, if the intention is to measure the first laser diode L of the second laser array 110, then voltage has to be applied to the first control terminal S1, which leads to an activation of all the switching transistors T1. The first column transistor T11 of the first column 20 is additionally activated.

The remaining switching transistors T2 to T14 and also the remaining column transistors T12, . . . of the first column 20 have to be switched off. Of the column transistors of the second column 30, the topmost column transistor T21 in the FIGURE has to be switched off, whereas the remaining column transistors T22, T23, etc. have to be switched on. What is thereby achieved is that a measurement current can flow from the first terminal P1 via the activated column transistor T11 and the switching transistor T1 through the first laser diode L of the second laser array 110 and reach the second column 30 of the switching matrix, from where the measurement or test current then passes to the fourth terminal P4 of the switching matrix 10.

Finally, an explanation will now also be given with respect to how, for example, the fourteenth laser diode of the second laser array 110 can be measured. For this purpose, firstly all the switching transistors T14 of the laser arrays are switched on via their common control terminal S14, which is not illustrated in the FIGURE for the sake of clarity. The remaining switching transistors T1, T2, . . . , T13 have to be switched off. The rest of the circuitry of the column and row transistors is exactly like that described in connection with the measurement at the first transistor of the second laser array 110.

What can thus be achieved with the switching matrix 10 in accordance with the FIGURE is that each laser L of each laser array can be driven individually.

It is possible, in addition, to drive the switching matrix 10 in such a way that current can be applied to all the laser diodes L simultaneously for an aging process or burn-in process.

We claim:

1. A method for performing test measurements on electrical components, which comprises:
initially disposing components on a carrier having a switching matrix and connecting the components to the switching matrix to allow the components to be switched on or off selectively;
simultaneously performing an aging process on all of the components by driving the switching matrix to switch on all of the components; and
performing test measurements by exclusively switching on the components to be measured.

2. The method according to claim 1, wherein at least some of the components form a group and the switching matrix is able to switch the group of the components on or off.

3. The method according to claim 1, which further comprises:
forming a group from at least some of the components to be tested;
connecting the switching matrix to switch the components of the group on or off collectively; and
switching the components of the group on collectively with the switching matrix to perform the test measurements.

4. The method according to claim 1, which further comprises connecting the components to the switching matrix to allow the switching matrix to switch the components on or off individually.

5. The method according to claim 1, which further comprises:
connecting the components to the switching matrix to allow the switching matrix to switch the components on or individually; and
switching the components on individually with the switching matrix to perform the test measurements.

6. The method according to claim 1, which further comprises using a semiconductor material as the carrier.

7. The method according to claim 6, which further comprises:
including a semiconductor switch in the switching matrix; and
at least partly monolithically integrating the semiconductor switch of the switching matrix in the semiconductor material.

8. The method according to claim 6, which further comprises using a silicon wafer as the semiconductor material.

9. The method according to claim 7, which further comprises forming the semiconductor switch with a transistor.

10. The method according to claim 9, which further comprises using a field-effect transistor as the transistor.

11. The method according to claim 1, which further comprises including a light-emitting component among the components.

12. The method according to claim 11, which further comprises using a light-emitting diode as the light-emitting component.

13. The method according to claim 11, which further comprises using a laser diode as the light-emitting component.

14. The method according to claim 12, which further comprises connecting a protective diode in parallel with the light-emitting diode.

15. The method according to claim 13, which further comprises connecting a protective diode in parallel with the laser diode.

16. The method according to claim 14, which further comprises:
connecting an anode of the protective diode to a cathode of the light-emitting diode; and
connecting a cathode of the protective diode to the anode of the light-emitting diode.

17. The method according to claim 15, which further comprises:
connecting an anode of the protective diode to a cathode of the laser diode; and
connecting a cathode of the protective diode to the anode of the light-emitting diode.

18. The method according to claim 1, which further comprises:
including a VCSEL laser in the components; and
performing the test measurements on the VCSEL laser.
